(19) United States
(12) Patent Application Publication
(10) Pub. No.: US 2009/0209108 A1
(43) Pub. Date: Aug. 20, 2009

(54) SUBSTRATE PROCESSING METHOD

(75) Inventors: Tsuyoshi MORIYA, Nirasaki-shi (JP); Eiichi Nishimura, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/388,858

(22) Filed: Feb. 19, 2009

Related U.S. Application Data
(60) Provisional application No. 61/055,558, filed on May 23, 2008.

(30) Foreign Application Priority Data
Feb. 20, 2008 (JP) 2008-039357

(51) Int. Cl. H01L 21/3065; H01L 21/306

(52) U.S. Cl. 438/710; 438/706; 257/E21.218; 257/E21.215

(57) ABSTRACT

A substrate processing method that can prevent a decrease in the yield of semiconductor devices manufactured from substrates. A gas containing fluorine atoms is supplied into a chamber, and then chlorine gas is supplied into the chamber. Further, a gas containing nitrogen atoms is supplied into the chamber.

### BACKGROUND OF THE INVENTION

1. Field of the Invention

The present invention relates to a substrate processing method, and in particular relates to a substrate processing method in which a substrate is subjected to processing using a gas containing fluorine atoms and a gas containing nitrogen atoms.

2. Description of the Related Art

In the case that in a processing container, a wafer for a semiconductor device (hereinafter referred to merely as a “wafer”) as a substrate is subjected to desired processing using a process gas, the process gas and water existing in the processing container react with a surface of the wafer e.g. silicon (Si), and as a result, reaction product is produced. If such reaction product remains as foreign matter on the wafer, short-circuiting of wiring occurs in a product manufactured from the wafer, for example, a semiconductor device, resulting in the yield of semiconductor devices decreasing.

In particular, water and fluorine atoms may cause foreign matter to be produced on the surface of the wafer with high probability. For example, if water remains on the wafer when carbon tetrafluoride (CF₄) gas is supplied toward the wafer, hydrogen fluoride (HF) is produced on the wafer due to chemical reaction of the water and fluorine atoms resulting from carbon tetrafluoride. The hydrogen fluoride has extremely high reactivity, and if, for example, ammonia (NH₃) gas is supplied as a cleaning gas toward the wafer, a chemical reaction expressed by the following equation (1) occurs, and a complex as reaction product is produced on the surface of the wafer. Subsequently, a chemical reaction expressed by the following equation (2) occurs, and silicon hydroxide (SiOH) is produced on the surface of the wafer, and the silicon hydroxide remains as foreign matter on the wafer.

6HF+2NH₃+Si→(NH₄)₂SiF₆+2H₂ (1)

2(NH₄)₂SiF₆+8NH₃+6H₂O→2SiOH+12NH₄F+2O₂+H₂ (2)

Therefore, removing water, fluorine atoms, and so on from a wafer has been demanded conventionally so as to prevent foreign matter from being produced on a wafer. Accordingly, for example, a method in which vacuum ultraviolet light is irradiated to a wafer under an inactive gas atmosphere or under a vacuum atmosphere has been disclosed (see, for example, Japanese Laid-open Patent Publication (Kokai) No. H07-335602) as a method of removing fluorine atoms on a wafer.

However, in the above described method in which vacuum ultraviolet light is irradiated, equipment for irradiating vacuum ultraviolet light is required, and on the other hand, water on a wafer cannot be positively removed. It is thus difficult to easily and reliably prevent foreign matter from being produced on a wafer. Moreover, a photoresist film formed on a wafer deteriorates due to the irradiation of vacuum ultraviolet light to the wafer. Thus, there is the problem that semiconductor devices are manufactured from a wafer on the surface of which foreign matter remains, a wafer whose photoresist film has deteriorated, and so on, resulting in the yield of the semiconductor devices ultimately manufactured decreasing.

### SUMMARY OF THE INVENTION

The present invention provides a substrate processing method that can prevent a decrease in the yield of semiconductor devices manufactured from substrates.

Accordingly, the present invention provides a substrate processing method in which processing is carried out on a substrate in a processing container, comprising a fluorine supplying step of supplying a gas containing fluorine atoms into the processing container, a chlorine supplying step of supplying chlorine gas into the processing container, and a nitrogen supplying step of supplying a gas containing nitrogen atoms into the processing container.

According to the present invention, the gas containing fluorine atoms is supplied into the processing container, the chlorine gas is supplied into the processing container, and further, the gas containing nitrogen atoms is supplied into the processing container. If the gas containing fluorine atoms is supplied in the case that water remains on the substrate, hydrogen fluoride is produced on the substrate, but after that, because the chlorine gas is supplied, the hydrogen fluoride reacts with the chlorine gas and turns into hydrogen chloride. Because the boiling point of the hydrogen chloride is considerably lower than the boiling point of the hydrogen fluoride so that the hydrogen chloride immediately vaporizes, the hydrogen chloride can be easily removed from the substrate. Moreover, even if water remains on the substrate when the hydrogen fluoride is produced, the water reacts with the chlorine gas and turns into hydrogen chloride, and hence the water can be easily removed from the substrate. That is, in the case that water remains on the substrate, even if a gas containing fluorine atoms is supplied toward the substrate, and hydrogen fluoride is produced, the hydrogen fluoride is converted into hydrogen chloride and easily removed from the substrate, and hence foreign matter can be simply and easily prevented from being produced on the substrate due to a chemical reaction of hydrogen fluoride and the gas containing nitrogen atoms. Similarly, water remaining on the substrate when the hydrogen fluoride is produced is also converted into hydrogen chloride, and hence foreign matter can be simply and easily prevented from being produced on the substrate due to the presence of water. Moreover, because there is no need to irradiate vacuum ultraviolet light to the substrate in order to remove fluorine, deterioration of a photoresist film on the substrate can be prevented. As a result, a decrease in the yield of the semiconductor devices manufactured from the substrates can be prevented.

The present invention can provide a substrate processing method, wherein in the chlorine supplying step, a temperature of the substrate is maintained at 20° C. or higher.

According to the present invention, the temperature of the substrate is maintained at 20° C. or higher when the chlorine gas is supplied. The boiling point of hydrogen fluoride is approximately 19.5° C. at atmospheric pressure, and the temperature of the substrate when the chlorine gas is supplied is higher than the boiling point of hydrogen fluoride, and hence even if, when the chlorine gas is supplied, hydrogen fluoride that has not reacted with the supplied chlorine gas remains, the hydrogen fluoride that has not reacted with the supplied chlorine gas can be reliably vaporized. As a result, a decrease in the yield of the semiconductor devices manufactured from the substrates can be reliably prevented.

The present invention can provide a substrate processing method, wherein in the chlorine supplying step, the substrate is heated to 200° C. or higher.

According to the present invention, the substrate is heated to 200° C. or higher when the chlorine gas is supplied. The temperature of the substrate when the chlorine gas is supplied is sufficiently higher than the boiling point of hydrogen fluoride, and hence even if, when the chlorine gas is supplied, hydrogen fluoride that has not reacted with the supplied chlorine gas remains, the hydrogen fluoride that has not reacted with the supplied chlorine gas can be more reliably vaporized. As a result, a decrease in the yield of the semiconductor devices manufactured from the substrates can be more reliably prevented.

The present invention can provide a substrate processing method, wherein in the fluorine supplying step, plasma processing is carried out on the substrate.

According to the present invention, because the plasma processing is carried out on the substrate in the fluorine supplying step, the substrate can be subjected to desired fabricating.

The present invention can provide a substrate processing method, wherein in the chlorine supplying step, plasma is not used.

According to the present invention, because plasma is not used in the chlorine supplying step, unwanted damage to the substrate can be prevented.

The present invention can provide a substrate processing method, wherein the gas containing fluorine atoms is fluorocarbon-based gas.

The present invention can provide a substrate processing method, wherein the gas containing nitrogen atoms is ammonia gas.

The features and advantages of the invention will become more apparent from the following detailed description taken in conjunction with the accompanying drawings.

### BRIEF DESCRIPTION OF THE DRAWINGS

FIG. 1 is a cross-sectional view schematically showing the construction of a substrate processing apparatus to which a substrate processing method according to an embodiment of the present invention is applied;

FIG. 2 is a flow chart of the substrate processing method according to the embodiment; and

FIG. 3 is a graph showing the relationship between the boiling points and the molecular weight of hydrogen fluoride, hydrogen chloride and hydrogen bromide.

### DETAILED DESCRIPTION OF PREFERRED EMBODIMENTS

The present invention will now be described in detail with reference to the drawings showing a preferred embodiment thereof.

First, a description will be given of a substrate processing apparatus to which a substrate processing method according to an embodiment of the present invention is applied.

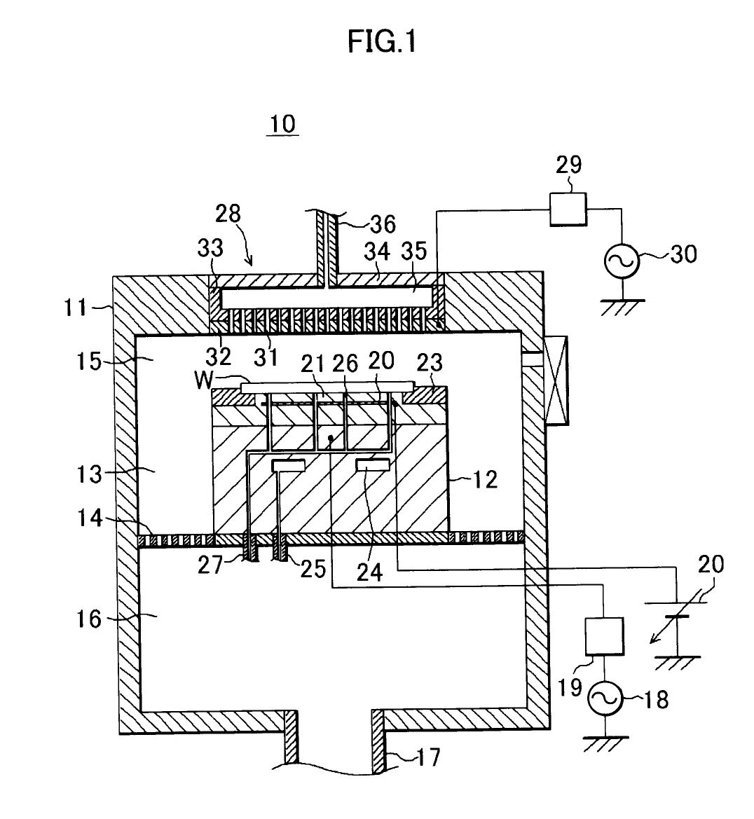

FIG. 1 is a cross-sectional view schematically showing the construction of the substrate processing apparatus to which the substrate processing method according to the present embodiment is applied. The substrate processing apparatus is constructed such as to carry out plasma etching on a semiconductor wafer as a substrate.

Referring to FIG. 1, the substrate processing apparatus 10 has a chamber 11 in which a wafer W having a diameter of, for example, 300 mm is accommodated, and a cylindrical susceptor 12 on which the wafer W is mounted is disposed in the chamber 11. Moreover, in the substrate processing apparatus 10, an exhaust flow path 13 that acts as a flow path through which gas above the susceptor 12 is exhausted out of the chamber 11 is formed between the inner wall of the chamber 11 and the side face of the susceptor 12. An exhaust plate 14 is disposed part way along the side exhaust path 13.

The exhaust plate 14 is a plate-shaped member having a large number of holes therein and acts as a partition plate that partitions the chamber 11 into an upper portion and a lower portion. In the upper portion (hereinafter referred to as the “reaction chamber”) 15 (processing container) of the chamber 11 partitioned by the exhaust plate 14, plasma is produced. An exhaust pipe 17 through which gas in the chamber 11 is exhausted is connected to the lower portion (hereinafter referred to as the “exhaust chamber (manifold)”) 16 of the chamber 11. The exhaust plate 14 captures or reflects plasma produced in the reaction chamber 15 to prevent leakage of the plasma into the manifold 16.

The exhaust pipe 17 has a TMP (turbo-molecular pump) and a DP (dry pump) (both not shown) connected thereto, and these pumps reduce the pressure in the chamber 11 down to a vacuum state. Specifically, the DP reduces the pressure in the chamber 11 from atmospheric pressure down to an intermediate vacuum state (e.g. a pressure of not more than 1.3×10 Pa (0.1 Torr)), and the TMP is operated in collaboration with the DP to reduce the pressure in the chamber 11 down to a high vacuum state (e.g. a pressure of not more than 1.3×10⁻³ Pa (1.0×10⁻⁵ Torr)), which is at a lower pressure than the intermediate vacuum state. It should be noted that an APC valve (not shown) controls the pressure in the chamber 11.

A lower radio frequency power source 18 is connected to the susceptor 12 in the chamber 11 via a lower matcher 19, and the lower radio frequency power source 18 supplies predetermined radio frequency electrical power to the susceptor 12. The susceptor 12 thus acts as a lower electrode. The lower matcher 19 reduces reflection of the radio frequency electrical power from the susceptor 12 so as to maximize the efficiency of the supply of the radio frequency electrical power into the susceptor 12.

An electrostatic chuck 21 having an electrostatic electrode plate 20 therein is provided in an upper portion of the susceptor 12. The electrostatic chuck 21 is formed by placing an upper disk-shaped member, which has a smaller diameter than a lower disk-shaped member having a certain diameter, over the lower disk-shaped member. It should be noted that the electrostatic chuck 21 is made of a ceramic. When a wafer W is mounted on the susceptor 12, the wafer W is disposed on the upper disk-shaped member of the electrostatic chuck 21.

A DC power source 22 is electrically connected to the electrostatic electrode plate 20 of the electrostatic chuck 21. Upon a positive DC high voltage being applied to the electrostatic electrode plate 20, a negative potential is produced on a surface of the wafer W which faces the electrostatic chuck 21 (hereinafter referred to as “the rear surface of the wafer W”). A potential difference thus arises between the electrostatic electrode plate 20 and the rear surface of the wafer W, and hence the wafer W is attracted to and held on the upper disk-shaped member of the electrostatic chuck 21 through a Coulomb force or a Johnsen-Rahbek force due to the potential difference.

Moreover, an annular focus ring 23 is mounted on the electrostatic chuck 21 such as to surround the attracted and held wafer W. The focus ring 23 is made of a conductive member such as silicon, and focuses plasma in the reaction chamber 15 toward a front surface of the wafer W, thus improving the efficiency of the plasma etching.

An annular coolant chamber 24 that extends, for example, in a circumferential direction of the susceptor 12 is provided inside the susceptor 12. A coolant, for example, cooling water or a Galden (registered trademark) fluid, at a low temperature is circulated through the coolant chamber 24 via a coolant piping 25 from a chiller unit (not shown). The susceptor 12 cooled by the low-temperature coolant cools the wafer W and the focus ring 23 via the electrostatic chuck 21.

A plurality of heat transfer gas supply holes 26 are opened to a portion of the upper surface of the upper disk-shaped member of the electrostatic chuck 21 on which the wafer W is attracted and held (hereinafter referred to as the “attracting surface”). The heat transfer gas supply holes 26 are connected to a heat-transmitting gas supply unit (not shown) by a heat-transmitting gas supply line 27, and the heat-transmitting gas supply unit supplies helium (He) gas as a heat transfer gas into a gap between the attracting surface and the rear surface of the wafer W via the heat transfer gas supply holes 26. The helium gas supplied into the gap between the attracting surface and the rear surface of the wafer W effectively transfers heat from the wafer W to the electrostatic chuck 21.

A showerhead 28 is disposed in a ceiling portion of the chamber 11 such as to face the susceptor 12. An upper radio frequency power source 30 is connected to the showerhead 28 via an upper matcher 29, and the upper radio frequency power source 30 supplies predetermined radio frequency electrical power to the showerhead 28. The showerhead 28 thus acts as an upper electrode. It should be noted the upper matcher 29 has a similar function to the lower matcher 19 described above.

The showerhead 28 has a ceiling electrode plate 32 having a number of gas holes 31 therein, a cooling plate 33 that detachably suspends the ceiling electrode plate 32, and a lid member 34 that covers the cooling plate 33. Moreover, a buffer chamber 35 is provided inside the cooling plate 33, and a process gas introducing pipe 36 is connected to the buffer chamber 35. The showerhead 28 supplies gas such as a process gas, a cleaning gas, and so on supplied to the buffer chamber 35 through the process gas introducing pipe 36 into the reaction chamber 15 via the gas holes 31. In the present embodiment, for example, fluorocarbon-based (CₓF_{y}) gas is supplied as the process gas into the reaction chamber 15, and for example, ammonia gas is supplied as the cleaning gas into the reaction chamber 15.

In the substrate processing apparatus 10, radio frequency electrical power is supplied to the susceptor 12 and the showerhead 28 to supply radio frequency electrical power into the reaction chamber 15, whereby the process gas supplied from the showerhead 28 is turned into high-density plasma in the reaction chamber 15. The wafer W is subjected to the plasma etching by the plasma.

Operation of the component parts of the above described substrate processing apparatus 10 is controlled in accordance with programs for the plasma etching by a CPU of a control unit (not shown) of the substrate processing apparatus 10.

In the conventional substrate processing method, after the wafer W is subjected to the plasma etching using a process gas containing fluorocarbon-based gas, and gas is exhausted out of the reaction chamber 15, ammonia gas is supplied into the reaction chamber 15. For this reason, hydrogen fluoride produced due to a chemical reaction of water and fluorine atoms originating from the process gas, remaining water (water that has not reacted with the fluorine atoms), and ammonia gas supplied thereafter react with silicon on the wafer W, and as a result, silicon hydroxide remains as foreign matter on the surface of the wafer W (see the above equations (1) and (2)).

On the other hand, in the present embodiment, chlorine gas is supplied into the reaction chamber 15 after the plasma etching using fluorocarbon-based gas.

Next, a description will be given of the substrate processing method according to the present embodiment.

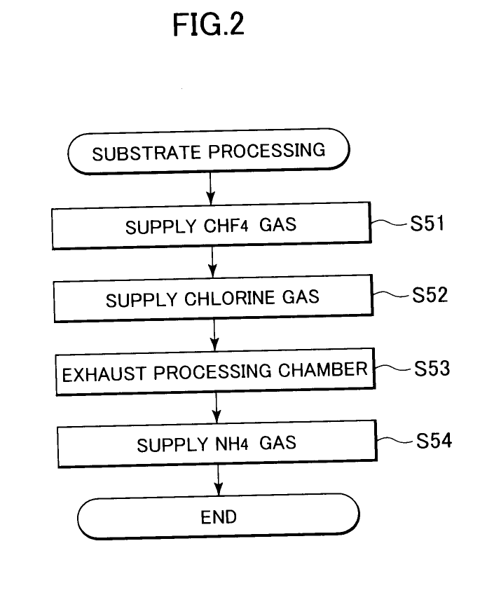

FIG. 2 is a flow chart of the substrate processing method according to the present embodiment.

Referring to FIG. 2, first, the showerhead 29 supplies a process gas containing carbon tetrafluoride (CF₄) gas into the reaction chamber 15 in which the wafer is accommodated (step S51). Further, the showerhead 28 and so on supply radio frequency electrical power into the reaction chamber 15, whereby the process gas is turned into plasma. A polysilicon layer on the wafer W is subjected to the plasma etching by the plasma. Here, if there is water on the wafer W, hydrogen fluoride is easily produced due to a chemical reaction of the water and fluorine atoms originating from the process gas.

Then, the showerhead 28 supplies chlorine gas into the reaction chamber 15 (step S52). When the chlorine gas reaches the water W and contacts the hydrogen fluoride and the remaining water on the wafer W, chemical reactions expressed by the following equations (3) and (4) occur:

2HF+Cl₂→2HCl+F₂ (3)

2H₂O+Cl₂→2HCl+O₂ (4)

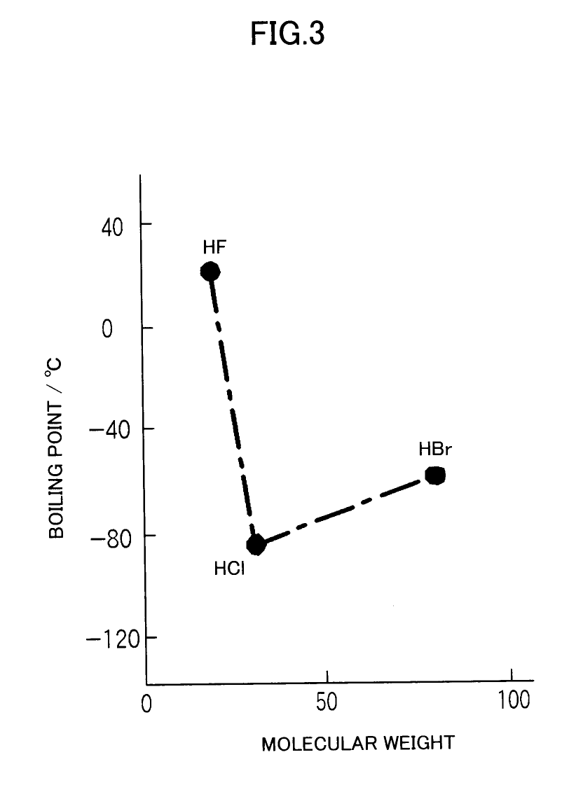

The boiling point of hydrogen chloride (HCl) produced by the chemical reactions expressed by the above equations (3) and (4) is considerably lower than the boiling points of hydrogen fluoride and water (see FIG. 3), and the hydrogen chloride vaporizes immediately after being produced. Thus, the hydrogen chloride is easily exhausted out of the reaction chamber 15 via the exhaust chamber 16 and the exhaust pipe 17 (step S53). After that, the showerhead 28 supplies ammonia gas into the reaction chamber 15 (step S54), and the wafer W is cleaned using the ammonia gas, followed by terminating the present process.

According to the substrate processing method of the present embodiment, the chlorine gas is supplied into the reaction chamber 15 after the plasma etching using the carbon tetrafluoride gas. At this time, as expressed by the above equations (3) and (4), the produced hydrogen fluoride and the remaining water are each converted into hydrogen chloride. Because the hydrogen chloride immediately vaporizes, the hydrogen chloride can be easily removed from the wafer W by exhausting the gas out of the reaction chamber 15. As a result, no hydrogen fluoride and water that cause foreign matter to be produced exists on the wafer W, and after that, even if ammonia gas is supplied into the reaction chamber 15, the reactions expressed by the above equations (1) and (2) do not occur, and foreign matter such as silicon hydroxide can be prevented from being produced on the wafer W. Moreover, because there is no need to irradiate vacuum ultraviolet light to the wafer W so as to remove fluorine atoms on the wafer W, deterioration of a photoresist film on the wafer W can be prevented. Therefore, a decrease in the yield of the semiconductor devices manufactured from the wafers W can be prevented.

Moreover, the boiling point of hydrogen chloride is sufficiently low, and produced hydrogen chloride easily vaporizes even at, for example, room temperature (approximately 20° C.) as described above, but in the present embodiment, because hydrogen chloride is produced on the wafer W heated to a high temperature by the plasma etching, the hydrogen chloride can be reliably vaporized.

Further, if the temperature of the wafer W when chlorine gas is supplied is higher than the boiling point of hydrogen fluoride, not only produced hydrogen chloride but also remaining hydrogen fluoride can be vaporized. Here, the boiling point of hydrogen fluoride is approximately 19.5° C. (see FIG. 3), and thus, particularly in the case that the temperature of the wafer W is maintained at than 20° C. or higher when the chlorine gas is supplied, hydrogen chloride and hydrogen fluoride can be reliably removed from the wafer W, and foreign matter can be more reliably prevented from being produced on the wafer W. Moreover, if the temperature of the wafer W is 100° C. or higher when the chlorine gas is supplied, the remaining water can be vaporized. For this reason, from the viewpoint of reliably preventing foreign matter from being produced, it is preferred that the wafer W is heated in advance before chlorine gas is supplied into the reaction chamber 15.

It should be noted that in the above described embodiment, carbon tetrafluoride gas and ammonia gas are used, but also in the case that other gas containing fluorine atoms and other gas containing nitrogen atoms are used, the same effects as the above described effects can be obtained by supplying chlorine gas after processing using the other gas containing fluorine atoms and before processing using the other gas containing nitrogen atoms.

Next, a concrete description will be given of examples of the present invention.

First, how the supply of chlorine gas affects production of foreign matter on the wafer was studied.

### Example 1

First, in the substrate processing apparatus 10, a process gas containing carbon tetrafluoride gas was supplied into the reaction chamber 15 in which a wafer W was accommodated. After that, the pressure in the reaction chamber 15 was reduced to a vacuum state, and radio frequency electrical power was supplied, whereby the process gas was turned into plasma. A polysilicon layer on the wafer W was subjected to the plasma etching using the plasma. Next, the pressure in the reaction chamber 15 was increased to atmospheric pressure, and a sufficient amount of chlorine gas was supplied into the reaction chamber 15. After that, the gas in the reaction chamber 15 is exhausted via the exhaust pipe 17. Subsequently, ammonia gas was supplied into the reaction chamber 15, and the wafer W was cleaned using the ammonia gas and then taken out from the chamber 11. Then, the surface of the wafer W was observed using a microscope, and it was ascertained that there was no foreign matter on the surface of the wafer W.

### Comparative Example 1

Next, in the substrate processing apparatus 10, ammonia gas was supplied into the reaction chamber 15 without supplying chlorine gas into the reaction chamber 15, and a wafer W was cleaned using the ammonia gas. The other conditions were set to be the same as those in the example 1. After the cleaning, the wafer W was taken out from the chamber 11. Then, the surface of the wafer W was observed using a microscope, and it was ascertained that foreign matter remained on the surface of the wafer W.

Thus, it was found that in the case that a wafer W having a polysilicon layer that has been subjected to the plasma etching using plasma produced from carbon tetrafluoride gas is cleaned using ammonia gas, foreign matter can be prevented from being produced on the wafer W if chlorine gas is supplied toward the wafer W after the plasma etching and before the cleaning.

Next, how the temperature of a wafer W when chlorine gas is supplied affects production of foreign matter on a wafer W was studied. It should be noted that in an example 2 and a comparative example 2 described below, a single gas comprised of hydrogen fluoride gas and a mixed gas comprised of hydrogen fluoride gas and nitrogen gas were supplied before chlorine gas was supplied to a wafer W that had been subjected to the plasma etching using plasma produced from carbon tetrafluoride gas so that an excessive amount of hydrogen fluoride can exist on the wafer W.

### Example 2

First, at atmospheric pressure, a single gas comprised of hydrogen fluoride gas was supplied to a wafer W that had been subjected to the plasma etching. Then, the wafer W was heated to a temperature of 200° C., and a mixed gas comprised of hydrogen fluoride gas and nitrogen gas was supplied to the wafer W. Next, chlorine gas was supplied toward the wafer W, and then ammonia gas was supplied toward the wafer W. Then, the surface of the wafer W was observed using a microscope, and it was ascertained that there was no foreign matter on the surface of the wafer W.

### Comparative Example 2

Next, a mixed gas comprised of hydrogen fluoride gas and nitrogen gas was supplied toward a wafer W that had been subjected to the plasma etching without heating the wafer W. The other conditions were set to be the same as those in the example 2. Then, the surface of the wafer W was observed using a microscope, and it was ascertained that foreign matter remained on the surface of the wafer W.

Thus, it was found that even if an excessive amount of hydrogen fluoride exists on a wafer W, foreign matter can be reliably prevented from being produced on the wafer W by supplying chlorine gas toward the wafer W that has been heated to 200° C. that is sufficiently higher than the boiling point of hydrogen chloride.

What is claimed is:

1. A substrate processing method in which processing is carried out on a substrate in a processing container, comprising:
a fluorine supplying step of supplying a gas containing fluorine atoms into the processing container;
a chlorine supplying step of supplying chlorine gas into the processing container; and
a nitrogen supplying step of supplying a gas containing nitrogen atoms into the processing container.

2. A substrate processing method as claimed in claim 1, wherein in said chlorine supplying step, a temperature of the substrate is maintained at 20° C. or higher.

3. A substrate processing method as claimed in claim 1, wherein in said chlorine supplying step, the substrate is heated to 200° C. or higher.

4. A substrate processing method as claimed in claim 1, wherein in said fluorine supplying step, plasma processing is carried out on the substrate.

5. A substrate processing method as claimed in claim 1, wherein in said chlorine supplying step, plasma is not used.

6. A substrate processing method as claimed in claim 1, wherein the gas containing fluorine atoms is fluorocarbon-based gas.

7. A substrate processing method as claimed in claim 1, wherein the gas containing nitrogen atoms is ammonia gas.
